(19) United States
(12) Patent Application Publication
(10) Pub. No.: US 2024/0365439 A1
(43) Pub. Date: Oct. 31, 2024

(54) CERAMIC HEATER

(71) Applicant: Niterra Co., Ltd., Nagoya-shi (JP)

(72) Inventors: Shusuke SEKIYA, Nagoya-shi (JP); Kohei MITSUYA, Nagoya-shi (JP)

(21) Appl. No.: 18/640,541

(22) Filed: Apr. 19, 2024

(30) Foreign Application Priority Data
Apr. 28, 2023 (JP) 2023-074521
Feb. 20, 2024 (JP) 2024-024095

(51) Int. Cl. H05B 3/06; H05B 3/14

(52) U.S. Cl. CPC H05B 3/06; H05B 3/143

(57) ABSTRACT

An upper surface of a ceramic base member of a ceramic heater includes a plurality of projected parts and a surrounding projected part. The surrounding projected parts surround the periphery of a lift-pin hole. In a case where the height of the surrounding projected part is H1 (m), the height of each of the plurality of projected parts is H2 (m), and a difference (H2−H1) between the height H2 (m) and the height H1 (m) is Δ (m), H1<H2 and 1×10⁻⁶ (m)≤Δ<50×10⁻⁶ (m) hold.

### REFERENCE TO RELATED APPLICATIONS

This application claims priorities from Japanese Patent Applications No. 2023-074521, filed on Apr. 28, 2023, and No. 2024-024095, filed on Feb. 20, 2024. The entire contents of the priority applications are incorporated herein by reference.

### BACKGROUND ART

The present disclosure relates to a ceramic heater which holds and heats a substrate such as a silicon wafer, etc.

Conventionally, there is a known ceramic heater in which a heating element is embedded in the inside thereof. In a certain known ceramic heater, a surface (heating surface) of a ceramic base member in which a substrate is placed is formed with a plurality of projected parts or projections (embossed parts) for the purpose of making a contact area with respect to the substrate small and/or a purpose of allowing gas to flow in a space defined by the substrate and the surface of the ceramic base member.

In the ceramic heater, generally, a heat spot is formed in a part of a substrate which is placed thereon, in some cases. The above-described publicly known ceramic heater attempts to suppress the formation of the heat spot by reducing the number (quantity) of the plurality of projected parts at an area overlapping with a heat spot.

### SUMMARY

In the ceramic base member of the ceramic heater, a lift-pin hole to which a lift pin is configured to displace the substrate in an up-down direction is formed in some cases. A surrounding projected part (peripheral projected part) configured to surround the lift-pin hole is formed in the surrounding (periphery) of the lift-pin hole so as to suppress such a situation that gas from an external environment flows via the lift-pin hole into the space defined by the substrate and the surface of the ceramic base member, in some cases. The inventors of the present disclosure found out that a heat spot may be generated at an area of the substrate which is immediately above the surrounding projected part.

The present disclosure has been made in view of the above-described circumstances; an object of the present disclosure is to provide a technique for suppressing such a situation that the gas from the external environment flows into, via the lift-pin hole, into the space defined by the substrate and the surface of the ceramic base member and suppressing the generation of the heat spot at the area, of the substrate, which is immediately above the surrounding projected part.

According to an aspect of the present disclosure, there is a ceramic heater including:
a ceramic base member having a disc shape and including an upper surface, a lower surface facing the upper surface in an up-down direction, and a through hole or a cutout part penetrating the ceramic base member from the upper surface to the lower surface; and
a heating element which is embedded in the ceramic base member or arranged on the lower surface of the ceramic base member,
wherein the ceramic base member includes:
   a plurality of projected parts configured to project upward to be higher than the upper surface of the ceramic base member; and
   a surrounding projected part arranged in a periphery of the through hole or the cutout part in the upper surface of the ceramic base member and configured to project upward to be higher than the upper surface of the ceramic base member, and H1<H2, and

$$1 \times 1 {0}^{- 6} ( m ) \leq Δ < 50 \times 1 {0}^{- 6} ( m )$$

are satisfied, wherein a length in the up-down direction from the upper surface of the ceramic base member to a top face of the surrounding projected part is H1 (m), a length in the up-down direction from the upper surface of the ceramic base member to a top surface of each of the plurality of projected parts is H2 (m), and a difference (H2−H1) between the length H2 (m) and the length H1 (m) is Δ (m).

As in the above-described configuration, in a case where the height from the upper surface of the ceramic base member to the top face of the surrounding projected part (the length in the up-down direction) is H1 (m), the height from the upper surface of the ceramic base member to the top surface of each of the plurality of projected parts is H2 (m), and the difference (H2−H1) between the length H2 (m) and the length H1 (m) is Δ (m) and that H1<H2 and 1×10⁻⁶ (m)≤Δ<50×10⁻⁶ (m) hold, it is possible to suppress a consumption amount of a gas in a case of attracting a wafer, placed on the ceramic heater, by vacuum suction. Further, it is also possible to suppress the generation of a heat spot at a part of the wafer immediately above the surrounding projected part.

### BRIEF DESCRIPTION OF DRAWINGS

FIG. 1 is a perspective view of a ceramic heater 100.

FIG. 2 is a view for explaining a schematic configuration of the ceramic heater 100.

FIG. 3 is a view for explaining a schematic configuration of an electrode 120.

FIG. 4 is a view for explaining a schematic configuration of a heater electrode 122.

FIGS. 5A to 5E are views depicting a flow of a method of producing the ceramic base member 110.

FIGS. 6A to 6D are views depicting a flow of another method of producing the ceramic base member 110.

FIG. 7 is a table summarizing the results of Examples 1 to 13 and Comparative Examples 1 and 2.

FIG. 8 is a schematic view for explaining a state that an annular projected part 152 and a surrounding projected part 157 cooperate to surround a periphery of a lift-pin hole 166.

FIG. 9 is a schematic view for explaining a state in which a surrounding projected part 157 is provided so as to surround a cutout part 166a.

### DESCRIPTION

### Ceramic Heater 100

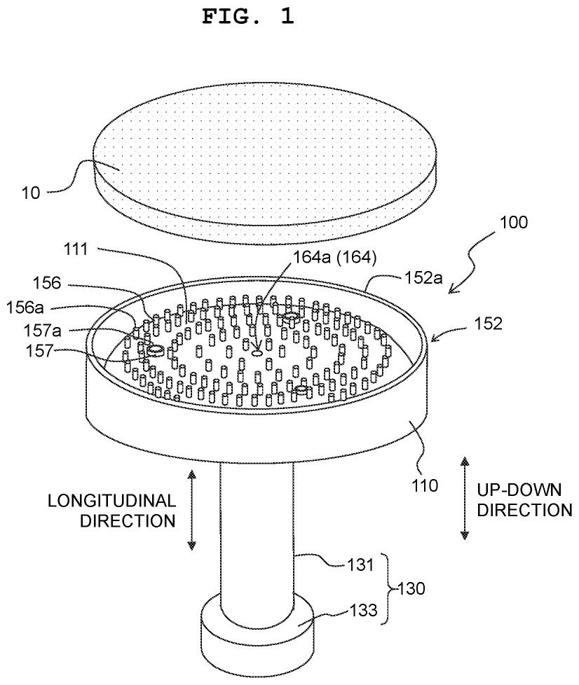

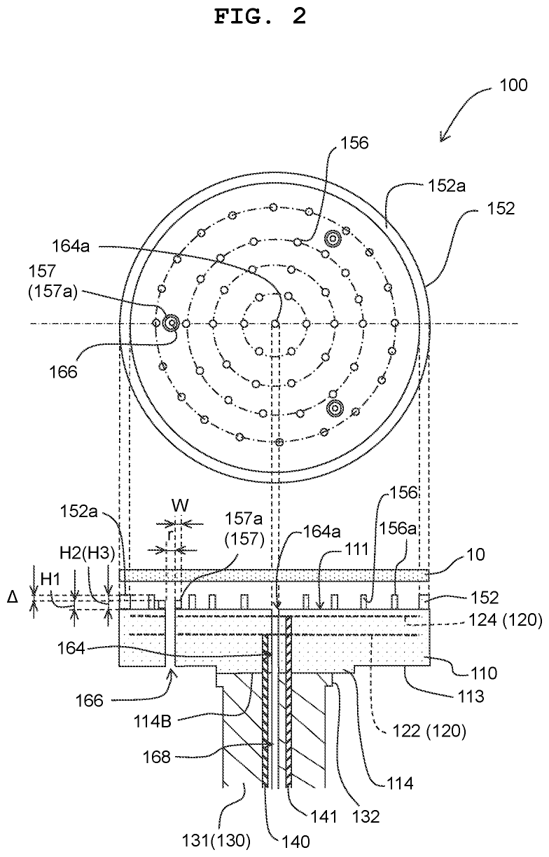

A ceramic heater 100, according to an embodiment of the present disclosure, will be explained, with reference to FIGS. 1 and 2. The ceramic heater 100, according to the present embodiment, is used, for example, for holding and heating semiconductor wafers (hereinafter referred simply to as a “wafer 10”) such as a silicon wafer, etc., in the inside of a semiconductor-producing apparatus. Note that in the following explanation, an up-down direction 5 is defined, with a state that the ceramic heater 100 is installed usably (a state depicted in FIG. 2) as the reference. As depicted in FIG. 2, the ceramic heater 100, according to the present embodiment, includes a ceramic base member 110, an electrode 120, and feeding lines 140 and 141.

The ceramic base member 110 is a member having the shape of a circular plate with a diameter of 12 inches (approximately 300 mm); a wafer 10 is placed on the ceramic base member 110. The ceramic base member 110 can be formed, for example, of a ceramic sintered body of aluminum nitride, silicon carbide, alumina, silicon nitride, etc. Note that in FIG. 2, the wafer 10 and the ceramic base member 110 are illustrated as being separated from each other so that the drawing can be easily seen. As depicted in FIG. 1, a projected part 152 having an annular (circular) shape (hereinafter referred to simply as an “annular projected part 152”) and a plurality of projected parts 156 are provided on an upper surface 111 of the ceramic base member 110. Note that in FIG. 2, the number (quantity) of the plurality of projected parts 156 is reduced so that the drawing is easily seen. Further, as depicted in FIG. 1, an opening 164a of a gas channel 164 (see FIG. 2) is formed in the center of the ceramic base member 110. The diameter of the opening 164a is 5 mm. Further, locations obtained by equally partitioning or dividing a circle with a radius of 80 mm into three parts are provided, respectively, with lift-pin holes 166. The diameter of each of the lift-pin holes 166 is 5 mm.

As depicted in FIGS. 1 and 2, the annular projected part 152 is a projected part having an annular (circular ring) shape and is arranged in the outer peripheral part (outer edge part) of the upper surface 111 of the ceramic base member 110 and projects upward from (to be higher than) the upper surface 111. As depicted in FIG. 2, in a case where the wafer 10 is placed on the ceramic base member 110, a top face 152a of the annular projected part 152 makes contact with a lower surface of the water 10. Namely, the annular projected part 152 is arranged at a position at which the annular projected part 152 overlaps with the wafer 10 in the up-down direction 5 in the case that the wafer 10 is placed on the ceramic base member 110.

The plurality of project parts 156 is provided on the upper surface 111 of the ceramic base member 110 at a location on the inside of the annular projected part 152. The plurality of project parts 156 is arranged coaxially (in concentric circles). The shape of a top face 156a of each of the plurality of projected parts 156 is circular. As depicted in FIG. 2, surrounding projected parts 157, each of which is configured to surround one of the lift-pin holes 166, arc arranged each at a surrounding (periphery) of one of the lift-pin holes 166. A top face 157a of each of the surrounding projected parts 157 has an annular (circular ring) shape; the center of the top face 157a is coincident with the center of one of the lift-pin holes 166 corresponding thereto. Note that locations at each of which one of the plurality of projected parts 156 is arranged and/or the number (quantity) of the plurality of projected parts 156 are/is appropriately set in accordance with the usage, action (operation), and function thereof. For example, in a case where a plurality of regular (equilateral) polygons, such as equilateral triangles, are spread over, each of the plurality of projected parts 156 can be arranged at a position of the apex of one of the plurality of regular polygons. Alternatively, the plurality of projected parts 156 can be arranged, respectively, at random positions.

In the following explanation, the height of each of the surrounding projected parts 157 is H1, the height of each of the plurality of projected parts 156 is H2, and the height of the annular projected part 152 is H3. Note that in the present specification, the height of each of the annular projected part 152 and the plurality of projected parts 156 is defined as a length in the up-down direction from the upper surface 111 of the ceramic base member 110. Note that in a case where the upper surface 111 of the ceramic base member 110 is not flat and, for example, has a stepped part, the highest position in the upper surface 111 of the ceramic base member 110 is made to be the reference, and the height of each of the annular projected part 152 and the plurality of projected parts 156 is defined as a length in the up-down direction from the highest position. It is preferred that each of the height Hl of the surrounding projected parts 157, the height H2 of the plurality of projected parts 156, and the height H3 of the annular projected part 152 is calculated with an average value of the values obtained at a plurality of locations. In a case where a plurality of locations is selected regarding the plurality of projected parts 156, it is preferred that nine or more locations are selected in an order from a projected part 156, among the plurality of projected parts 156, which is the closest to one of the surrounding projected parts 157. In a case where a plurality of locations is selected regarding each of the surrounding projected parts 157, it is preferred to adopt locations obtained by dividing a center line of each of the surrounding projected parts 157 equally into two or more parts in the circumferential direction. In a case where a plurality of locations is selected regarding the annular projected part 152, it is preferred to adopt locations obtained by dividing a center line of the annular projected part 152 equally into eight or more parts in the circumferential direction. In the present embodiment, the height H2 of the plurality of projected parts 156 and the height H3 of the annular projected part 152 are the same and may be made in a range of 5 μm to 2 mm. In contrast, the height Hl of each of the surrounding projected parts 157 is lower than the height H2 of the plurality of projected parts 156; in a case where a difference between the height H2 of the plurality of projected parts 156 and the height H1 of each of the surrounding projected parts 157 is made Δ(=H2−H1), 1 μm≤Δ<50 μm holds.

The width of the top face 152a of the annular projected part 152 is preferably a constant (given) width and may be made in a range of 0.1 mm to 10 mm. A center line average roughness Ra in the top face 152a of the annular projected part 152 can be made to be 1.6 μm or less. Note that the center line average roughness Ra represents unevenness or roughness (concave parts and convex parts) in a surface by an average of the absolute values of deviations from the center line thereof. Similarly, a center line average roughness Ra in the top face 156a of the plurality of projected parts 156 can be made to be 1.6 μm or less. Note that the center line average roughness Ra in each of the top face 152a of the annular projected part 152 and the top face 156a of the plurality of projected parts 156 is preferably 0.4 μm or less, more preferably 0.2 μm or less and further more preferably 0.1 μm or less.

A clearance (spacing distance) between respective projected parts of the plurality of projected parts 156 can be made in a range of 1.5 mm to 30 mm.

As described above, the opening 164a of the gas channel 164 is opened at the substantial center in the upper surface 111 (see FIG. 2). The gas channel 164 includes the opening 164a and is formed inside the ceramic base member 110. In the present embodiment, the gas channel 164 extends downward from the opening 164a. The gas channel 164 can be used as a channel for supplying gas to a space (gap) defined by the upper surface 111 of the ceramic base member 110 and the lower surface of the wafer 10. For example, it is possible, via the gas channel 164, to supply a heat transfer gas for heat transfer between the wafer 10 and the ceramic base member 110. As heat transfer gas, for example, it is possible to use an inert gas such as helium, argon, nitrogen gas, etc. The heat transfer gas is supplied via the gas channel 164 at a pressure which is set within a range of 100 Pa to 40000 Pa. Further, in a case where a process gas enters into a gap in the inside of the annular projected part 152, from a gap between the top face 152a of the annular projected part 152 and the lower surface of the wafer 10, it is possible to exhaust (discharge) the process gas via the gas channel 164. In this situation, by adjusting the exhaust pressure, it is possible to adjust a differential pressure between the pressure at the outside of the gap and the pressure at the inside of the gap. With this, it is possible to attract the wafer 10, by suction, toward the upper surface 111 of the ceramic base member 110. Furthermore, also in a case where the process gas enters from a gap between the upper surface of each of the surrounding projected parts 157 and the lower surface of the wafer 10, it is possible to exhaust or discharge the process gas via the gas channel 164.

As depicted in FIG. 2, the electrode 120 is embedded in the inside of the ceramic base member 110. The electrode 120 includes a heater electrode 122 and an electrostatic attraction electrode 124. The electrostatic attraction electrode 124 is embedded in the inside of the ceramic base member, at a location above the heater electrode 122.

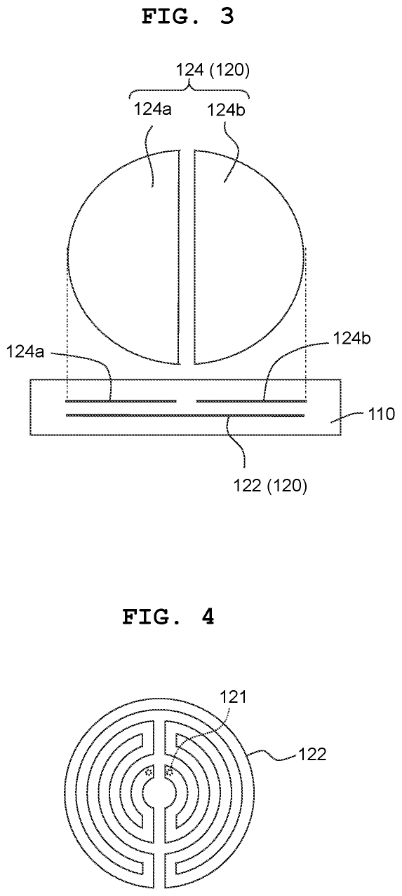

As depicted in FIG. 3, the electrostatic attraction electrode 124 is arranged such that two semi-circular electrodes 124a and 124b face each other at a predetermined spacing distance, and has, as a whole, a substantially circular shape. In the present embodiment, the outer diameter of the electrostatic attraction electrode 124 is 292 mm. By applying a predetermined voltage (for example, ±500V) to each of the electrodes 124a and the electrode 124b, it is possible to attract the wafer 10 by the electrostatic suction.

As depicted in FIG. 4, the heater electrode 122 is a metallic mesh or foil that is cut into the shape of a belt or band. The outer diameter of the heater electrode 122 is 298 mm. The heater electrode 122 is not exposed from the side surface of the ceramic base member 110. A terminal part 121, which is connected to the feeding line 140 (see FIG. 2), is provided at a substantially central part of the heater electrode 122. The heater electrode 122 is formed of a heat-resisting metal (high melting point metal) such as, for example, a foil including tungsten (W), molybdenum (Mo), or an alloy including the molybdenum and/or the tungsten, or a mesh which is obtained by weaving a wire including tungsten (W), molybdenum (Mo) or an alloy including the molybdenum and/or the tungsten; etc. It is preferred that the purity of each of the tungsten and the molybdenum is 99% or more. The thickness of the heater electrode 122 is 0.15 mm or less. Note that from the viewpoint of making the resistance value of the heater electrode 122 to be high to thereby reduce the current consumption of the ceramic heater 100, it is preferred that the wire diameter of the wire is made to be 0.1 mm or less and that the thickness of the heater electrode 122 is made to be 0.1 mm or less, except for an intersection point of the wire. Further, the width of the heater electrode 122, which is cut into the shape of the band, is preferably in a range of 2.5 mm to 20 mm, more preferably in a range of 5 mm to 15 mm. In the present embodiment, although the heater electrode 122 is cut in the shape depicted in FIG. 4, the shape of the heater electrode 122 is not limited to this and may be changed as appropriate. Note that it is allowable that a plasma electrode configured to generate a plasma at a location above the ceramic base member 110 is embedded in the inside of the ceramic base member 110, in addition to the heater electrode 122 or instead of the heater electrode 122.

As depicted in FIG. 2, the feeding line 140 configured to supply an electric power to the heater electrode 122 and the feeding line 141 configured to supply the electric power to the electrostatic attraction electrode 124 are arranged in the ceramic heater 100. Note that in FIG. 2, although only one of the feeding lines 140 and one of the feeding lines 141 are depicted, a plurality of feeding lines 140 and a plurality of feeding lines 141 are actually arranged. An upper end of the feeding line 140 is electrically connected to the terminal part 121 (see FIG. 4) arranged in the center of the heater electrode 122. The feeding line 140 is connected to a non-illustrated power source for the heater. With this, the electric power is supplied to the heater electrode 122 via the feeding line 140. Similarly, the electric power is supplied to the electrostatic attraction electrode 124 via the feeding line 141.

Next, an explanation of the method of producing the ceramic heater 100 will be given. In the following, a case in which the ceramic base member 110 is formed of aluminum nitride will be explained as an example.

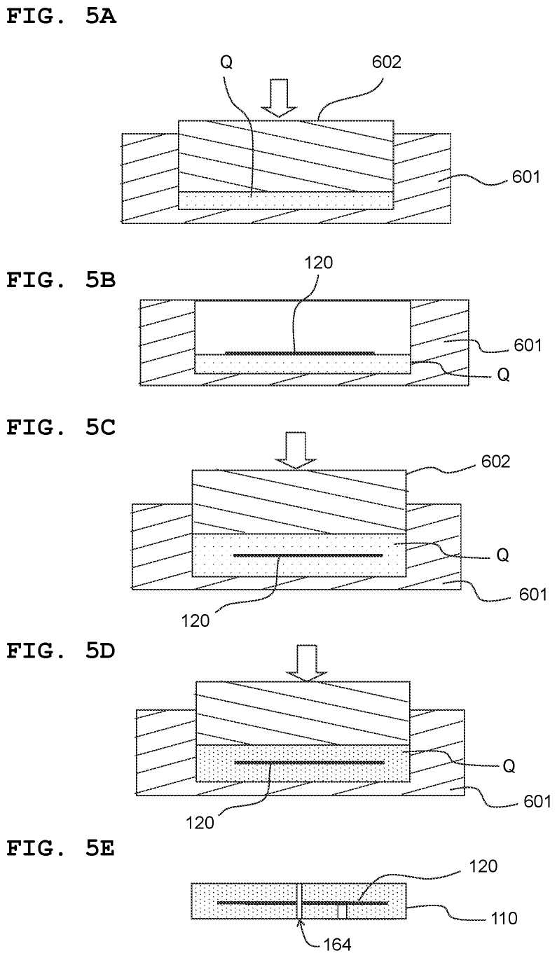

First, a method of producing the ceramic base member 110 will be explained. Note that for simplifying the explanation, it is presumed that only the heater electrode 122 is embedded, as the electrode 120, in the inside of the ceramic base member 111. As depicted in FIG. 5A, granulated powder Q, which contains aluminum nitride (AlN) powder as a main component thereof, is charged to a bottomed mold 601 made of carbon and is subjected to a temporary pressing with a punch 602. Note that it is preferred that 5 wt % or less of the sintering agent (for example, Y₂O₃) is included in the granulated powder Q. Next, as depicted in FIG. 5B, the heater electrode 122, which is cut to a predetermined shape, is arranged on the temporarily pressed granulated powder Q. Note that the heater electrode 122 is arranged to be parallel to a plane orthogonal to a pressing direction (the bottom surface of the bottomed mold 601). In this situation, it is allowable to embed a pellet formed of tungsten (W) or molybdenum (Mo) at a position of the terminal 121 (see FIG. 4) of the heater electrode 122.

As depicted in FIG. 5C, the granulated power Q is further charged to the bottomed mold 601 so as to cover the heater electrode 122 and is subjected to molding while being pressed with the punch 602. Next, as depicted in FIG. 5D, the baking is performed for the granulated power Q in which the heater electrode 122 is embedded in a state where the granulated power Q is pressed. The pressure applied during the baking is preferably 1 MPa or more. Further, it is preferred that the baking is performed at a temperature which is 1800° C. or more. Next, as depicted in FIG. 5E, the blind hole driving process is performed up to a location of the heater electrode 122 so as to form the terminal 121. Note that in a case where the pellet is embedded, the blind hole driving process can be performed up to the location of the pellet. Further, a through hole, which becomes a part of gas channel 164, is formed. With this, it is possible to produce a ceramic base member 110 in which the gas channel 164 is formed in the inside thereof. In this case, it is preferred that a predetermined opening is provided in advance on the heater electrode 122 so that the heater electrode 122 is not exposed from the gas channel 164.

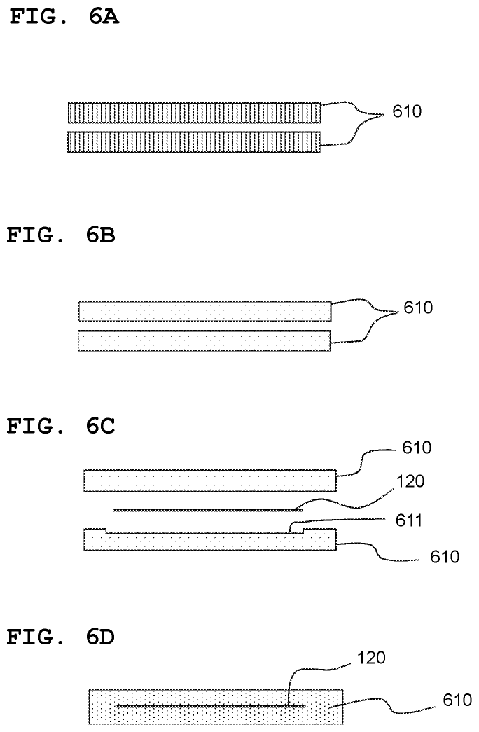

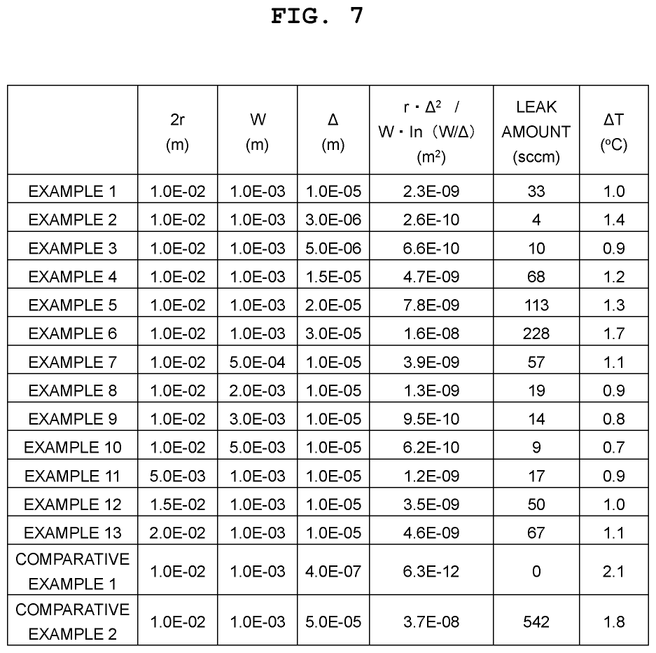

Note that the ceramic base member 110 can also be formed by the following method. As depicted in FIG. 6A, a binder is added to the granulated powder Q of the aluminum nitride so as to perform the CIP (Cold Isostatic Press) molding followed by being processed to have a disc shape, thereby producing molded bodies (compacts) 610 of the aluminum nitride. Next, as depicted in FIG. 6B, a degreasing process is performed for the molded bodies 610 so as to remove the binder.

As depicted in FIG. 6C, a recessed part 611 for embedding the heater electrode 122 is formed in a degreased molded body 610 of the degreased molded bodies 610. The heater electrode 122 is arranged in the recessed part 611 formed in the molded body 610, and another molded body 610 of the molded bodies 610 is stacked on the molded body 610. It is also allowable to form the recessed part 611 in advance in the molded body 610. Next, as depicted in FIG. 6D, the molded bodies 610 which are stacked so as to sandwich the heater electrode 122 therebetween is subjected to the baking in a state that the stacked molded bodies 610 are pressed, thereby preparing a baked body. It is preferred that the pressure applied during the baking is 1 MPa or more. Further, it is preferred that the basking is performed at a temperature which is 1800° C. or more. Since the steps after producing the baked boy are similar to the steps as described above, any explanation therefor will be omitted.

Grinding is performed with respect to the upper surface 111 of the ceramic base member 110 formed in such a manner, and a lapping process (mirror surface polishing process) is performed. Further, by performing a sandblasting process with respect to the upper surface 111, the plurality of projected parts 156, the surrounding projecting parts 157, and the annular projected part 152 are formed in the upper surface 111. In this situation, the process is performed so that the height of the plurality of projected parts 156 and the height of the surrounding projecting parts 157 are the same. Further, the top face 152a of the annular projected part 152 is processed to have a predetermined shape. Note that although the sandblasting process is suitable as a method of forming the processing method for forming the plurality of projected parts 156, the surrounding projecting parts 157, and the annular projected part 152, it is allowable to use another processing method different from the sandblasting process.

### EXAMPLES

In the following, the present disclosure will be further explained by using Examples 1 to 13. Note that, however, the present disclosure is not limited to or restricted by the examples to be explained below. Note that FIG. 7 depicts a table summarizing the results of Examples 1 to 13 and Comparative Examples 1 and 2.

### Example 1

A ceramic heater 100 (see FIG. 2) of Example 1 will be explained. In Example 1, a ceramic base member 110, of which diameter is 300 mm and thickness is 15 mm, was prepared with aluminum nitride (AIN) to which 5 wt % of the sintering agent (Y₂O₃) was added, and with the above-described producing method. Note that the above-described electrostatic attraction electrode 124 was not embedded in the ceramic heater 100 of Example 1, and the heater electrode 122 having the shape as depicted in FIG. 3 is embedded in the ceramic base member 110 of Example 1.

The opening 164a of the gas channel 164 (see FIG. 2) was provided at the center of the ceramic base member 110. The diameter of the opening 164a was 4 mm. Further, the lift-pin holes 166 were provided, respectively, at locations (positions) obtained by equally partitioning a circle having a radius of 64 mm (a virtual circle having a pitch diameter of 128 mm) into three parts. The diameter of each of the lift-pin holes 166 was 4 mm.

An annular projected part 152, having an inner diameter of 296 mm, an outer diameter of 300 mm, and a width of 2 mm, was formed in the upper surface 111 of the ceramic base member 110. The height H3 of the annular projected part 152 was made to be 150 μm. Further, a plurality of projected parts 156 having a cylindrical (columnar) shape was formed in the upper surface 111 of the ceramic base member 110. The shape of the top face 156a of each of the plurality of projected parts 156 was made to be the shape of a circle having a diameter of 3 mm. The height H2 of each of the plurality of projected parts 156 was made to be 150 μm. The plurality of projected parts 156 was arranged side by side at equal spacing distances of 8 mm to 12 mm on concentric circles whose diameters were in a range of 20 mm to 140 mm and which were arranged with spacing distances of 10 mm therebetween. Surrounding projected parts, 157 were formed in the upper surface 111 of the ceramic base member 100, each at a position surrounding one of the lift-pin holes 166. The top face 157a of each of the surrounding projected parts 157 had the shape of an annular ring shape in which a diameter 2r was 10 mm (10×10⁻³ m), and a width W was 1 mm (1.0×10⁻³ m). The height H1 of each of the surrounding projected parts 157 was made to be 140 μm. Namely, the difference Δ between the height H2 and the height H1 was made to be 10 μm (1.0×10⁻⁵ m). Note that the center line average roughness Ra in each of the top face 152a of the annular projected part 152, the top face 156a of the plurality of projected parts 156, and the top face 157a of the surrounding projected parts 157 was made to be 0.4 μm.

The ceramic heater 100, having such a shape, was set in a vacuum chamber, and a silicon wafer for temperature evaluation with a diameter of 300 mm was placed in the ceramic heater 100. Further, a non-illustrated external power source was connected to the heater electrode 122 of the ceramic heater 100. An evaluation of the amount of leaked gas (gas leak amount) at the time of attracting the silicon wafer by the vacuum suction and an evaluation of the temperature distribution in the silicon wafer were each performed using the following procedure.

In the evaluation of the gas leak amount, the pressure inside the vacuum chamber was decreased to 200 Torr, the gas channel 164 was connected to a non-illustrated gas exhausting apparatus, and the pressure in an exhaust hole of the gas exhausting apparatus was made to be 50 Torr. With this, the silicon wafer was attracted, by the vacuum suction, with a differential pressure (150 Torr). Note that the leak amount of the gas corresponds mainly to the flow amount of the gas exhausted from the gas channel 164 via a gap between the top face 157a of each of the surrounding projected parts 157 and the lower surface of the silicon wafer. According to the knowledge of the inventors of the present disclosure, the gas leak amount depends on the conductance of the gap between the top face 157a of each of the surrounding projected parts 157 and the lower surface of the silicon wafer; the conductance is characterized by a value r·Δ²/W·ln(W/Δ). In Example 1, the value r·Δ²/W·ln(W/Δ) was 2.3×10⁻⁹ (m²), and the gas leak amount was 33 sccm. The gas leak amount was 100 sccm or less, and the evaluation of the leak amount was determined to be satisfactory.

In the evaluation of the temperature distribution of the silicon wafer, in a state that the silicon wafer for temperature evaluation was attracted by the vacuum suction with the above-described procedure, an output electric power of the external power source was adjusted so that the temperature of the upper surface of the silicon wafer became to be 500° C. in a stationary state. Afterward, the temperature distribution of the silicon wafer for temperature evaluation was measured by an infrared camera. A temperature difference ΔT was measured on the upper surface of the silicon wafer, at a position immediately above each of the surrounding projected parts 157, with both ends which were apart from each other by ±15 mm from the center of the through hole on a line crossing each of the surrounding projected parts 157 as a range. In Example 1, the temperature difference ΔT was 1.0° C. The temperature difference ΔT was 2.0° C. or less, and the evaluation of the temperature distribution of the silicon wafer was determined to be satisfactory.

### Example 2

A ceramic heater 100 of Example 2 has a configuration similar to the configuration of the ceramic heater 100 of Example 1, except that the height H1 of each of the surrounding projected parts 157 was made to be 147 μm and that the difference Δ between the height H2 and the height H1 was made to be 3 μm (3×10⁻⁶ m).

The ceramic heater 100, having such a shape, was set in the vacuum chamber, and a silicon wafer for temperature evaluation, which was similar to that in Example 1, was placed in the ceramic heater 100. Further, the measurement of the gas leak amount and the evaluation of the temperature distribution of the silicon wafer were performed in procedures similar to the procedures in Example 1. In Example 2, the value r·Δ²/W·ln(W/Δ) was 2.6×10⁻¹⁰ (m²), and the gas leak amount was 4 sccm. The gas leak amount was 100 sccm or less, and the evaluation of the leak amount was determined to be satisfactory. In Example 2, the temperature difference ΔT was 1.4° C. The temperature difference ΔT was 2.0° C. or less, and the evaluation of the temperature distribution of the silicon wafer was determined to be satisfactory.

### Example 3

A ceramic heater 100 of Example 3 has a configuration similar to the configuration of the ceramic heater 100 of Example 1, except that the height H1 of each of the surrounding projected parts 157 was made to be 145 μm and that the difference Δ between the height H2 and the height H1 was made to be 5 μm (5×10⁻⁶ m).

The ceramic heater 100, having such a shape, was set in the vacuum chamber, and a silicon wafer for temperature evaluation, which was similar to that in Example 1, was placed in the ceramic heater 100. Further, the measurement of the gas leak amount and the evaluation of the temperature distribution of the silicon wafer were performed in procedures similar to the procedures in Example 1. In Example 3, the value r·Δ²/W·ln(W/Δ) was 6.6×10⁻¹⁰ (m²), and the gas leak amount was 10 sccm. The gas leak amount was 100 sccm or less, and the evaluation of the leak amount was determined to be satisfactory. In Example 3, the temperature difference ΔT was 0.9° C. The temperature difference ΔT was 2.0° C. or less, and the evaluation of the temperature distribution of the silicon wafer was determined to be satisfactory.

### Example 4

A ceramic heater 100 of Example 4 has a configuration similar to the configuration of the ceramic heater 100 of Example 1, except that the height H1 of each of the surrounding projected parts 157 was made to be 135 μm and that the difference Δ between the height H2 and the height H1 was made to be 15 μm (1.5×10⁻⁵ m).

The ceramic heater 100, having such a shape, was set in the vacuum chamber, and a silicon wafer for temperature evaluation, which was similar to that in Example 1, was placed in the ceramic heater 100. Further, the measurement of the gas leak amount and the evaluation of the temperature distribution of the silicon wafer were performed in procedures similar to the procedures in Example 1. In Example 4, the value r·Δ²/W·ln(W/Δ) was 4.7×10⁻⁹ (m²), and the gas leak amount was 68 sccm. The gas leak amount was 100 sccm or less, and the evaluation of the leak amount was determined to be satisfactory. In Example 4, the temperature difference ΔT was 1.2° C. The temperature difference ΔT was 2.0° C. or less, and the evaluation of the temperature distribution of the silicon wafer was determined to be satisfactory.

### Example 5

A ceramic heater 100 of Example 5 has a configuration similar to the configuration of the ceramic heater 100 of Example 1, except that the height H1 of each of the surrounding projected parts 157 was made to be 130 μm and that the difference Δ between the height H2 and the height H1 was made to be 20 μm (2.0×10⁻⁵ m).

The ceramic heater 100, having such a shape, was set in the vacuum chamber, and a silicon wafer for temperature evaluation, which was similar to that in Example 1, was placed in the ceramic heater 100. Further, the measurement of the gas leak amount and the evaluation of the temperature distribution of the silicon wafer were performed in procedures similar to the procedures in Example 1. In Example 5, the value r·Δ²/W·ln(W/Δ) was 7.8×10⁻⁹ (m²), and the gas leak amount was 113 sccm. Although the gas leak amount exceeded 100 sccm but was 300 sccm or less, the evaluation of the leak amount was determined to be fair. In Example 5, the temperature difference ΔT was 1.3° C. The temperature difference ΔT was 2.0° C. or less, and the evaluation of the temperature distribution of the silicon wafer was determined to be satisfactory.

### Example 6

A ceramic heater 100 of Example 6 has a configuration similar to the configuration of the ceramic heater 100 of Example 1, except that the height H1 of each of the surrounding projected parts 157 was made to be 120 μm and that the difference Δ between the height H2 and the height H1 was made to be 30 μm (3.0×10⁻⁵ m).

The ceramic heater 100, having such a shape, was set in the vacuum chamber, and a silicon wafer for temperature evaluation, which was similar to that in Example 1, was placed in the ceramic heater 100. Further, the measurement of the gas leak amount and the evaluation of the temperature distribution of the silicon wafer were performed in procedures similar to the procedures in Example 1. In Example 6, the value r·Δ²/W·ln(W/Δ) was 1.6×10⁻⁸ (m²), and the gas leak amount was 228 sccm. Although the gas leak amount exceeded 100 sccm but was 300 sccm or less, the evaluation of the leak amount was determined to be fair. In Example 6, the temperature difference ΔT was 1.7° C. The temperature difference ΔT was 2.0° C. or less, and the evaluation of the temperature distribution of the silicon wafer was determined to be satisfactory.

### Example 7

A ceramic heater 100 of Example 7 has a configuration similar to the configuration of the ceramic heater 100 of Example 1, except that the width W of each of the surrounding projected parts 157 was made to 0.5 mm (5.0×10⁻⁴ m).

The ceramic heater 100, having such a shape, was set in the vacuum chamber, and a silicon wafer for temperature evaluation, which was similar to that in Example 1, was placed in the ceramic heater 100. Further, the measurement of the gas leak amount and the evaluation of the temperature distribution of the silicon wafer were performed in procedures similar to the procedures in Example 1. In Example 7, the value r·Δ²/W·ln(W/Δ) was 3.9×10⁻⁹ (m²), and the gas leak amount was 57 sccm. The gas leak amount was 100 sccm or less, and the evaluation of the leak amount was determined to be satisfactory. In Example 7, the temperature difference ΔT was 1.1° C. The temperature difference ΔT was 2.0° C. or less, and the evaluation of the temperature distribution of the silicon wafer was determined to be satisfactory.

### Example 8

A ceramic heater 100 of Example 8 has a configuration similar to the configuration of the ceramic heater 100 of Example 1, except that the width W of each of the surrounding projected parts 157 was made to 2 mm (2.0×10⁻³ m).

The ceramic heater 100, having such a shape, was set in the vacuum chamber, and a silicon wafer for temperature evaluation, which was similar to that in Example 1, was placed in the ceramic heater 100. Further, the measurement of the gas leak amount and the evaluation of the temperature distribution of the silicon wafer were performed in procedures similar to the procedures in Example 1. In Example 8, the value r·Δ²/W·ln(W/Δ) was 1.3×10⁻⁹ (m²), and the gas leak amount was 19 sccm. The gas leak amount was 100 sccm or less, and the evaluation of the leak amount was determined to be satisfactory. In Example 8, the temperature difference ΔT was 0.9° C. The temperature difference ΔT was 2.0° C. or less, and the evaluation of the temperature distribution of the silicon wafer was determined to be satisfactory.

### Example 9

A ceramic heater 100 of Example 9 has a configuration similar to the configuration of the ceramic heater 100 of Example 1, except that the width W of each of the surrounding projected parts 157 was made to 3 mm (3.0×10⁻³ m).

The ceramic heater 100, having such a shape, was set in the vacuum chamber, and a silicon wafer for temperature evaluation, which was similar to that in Example 1, was placed in the ceramic heater 100. Further, the measurement of the gas leak amount and the evaluation of the temperature distribution of the silicon wafer were performed in procedures similar to the procedures in Example 1. In Example 9, the value r·Δ²/W·ln(W/Δ) was 9.5×10⁻¹⁰ (m²), and the gas leak amount was 14 sccm. The gas leak amount was 100 sccm or less, and the evaluation of the leak amount was determined to be satisfactory. In Example 9, the temperature difference ΔT was 0.8° C. The temperature difference ΔT was 2.0° C. or less, and the evaluation of the temperature distribution of the silicon wafer was determined to be satisfactory.

### Example 10

A ceramic heater 100 of Example 10 has a configuration similar to the configuration of the ceramic heater 100 of Example 1, except that the width W of each of the surrounding projected parts 157 was made to 5 mm (5.0×10⁻³ m).

The ceramic heater 100, having such a shape, was set in the vacuum chamber, and a silicon wafer for temperature evaluation, which was similar to that in Example 1, was placed in the ceramic heater 100. Further, the measurement of the gas leak amount and the evaluation of the temperature distribution of the silicon wafer were performed in procedures similar to the procedures in Example 1. In Example 10, the value r·Δ²/W·ln(W/Δ) was 6.2×10⁻¹⁰ (m²), and the gas leak amount was 9 sccm. The gas leak amount was 100 sccm or less, and the evaluation of the leak amount was determined to be satisfactory. In Example 10, the temperature difference ΔT was 0.7° C. The temperature difference ΔT was 2.0° C. or less, and the evaluation of the temperature distribution of the silicon wafer was determined to be satisfactory.

### Example 11

A ceramic heater 100 of Example 11 has a configuration similar to the configuration of the ceramic heater 100 of Example 1, except that the diameter 2r of each of the surrounding projected parts 157 was made to 5 mm (5.0×10⁻³ m).

The ceramic heater 100, having such a shape, was set in the vacuum chamber, and a silicon wafer for temperature evaluation, which was similar to that in Example 1, was placed in the ceramic heater 100. Further, the measurement of the gas leak amount and the evaluation of the temperature distribution of the silicon wafer were performed in procedures similar to the procedures in Example 1. In Example 11, the value r·Δ²/W·ln(W/Δ) was 1.2×10⁻⁹ (m²), and the gas leak amount was 17 sccm. The gas leak amount was 100 sccm or less, and the evaluation of the leak amount was determined to be satisfactory. In Example 11, the temperature difference ΔT was 0.9° C. The temperature difference ΔT was 2.0° C. or less, and the evaluation of the temperature distribution of the silicon wafer was determined to be satisfactory.

### Example 12

A ceramic heater 100 of Example 12 has a configuration similar to the configuration of the ceramic heater 100 of Example 1, except that the diameter 2r of each of the surrounding projected parts 157 was made to 15 mm (1.5×10⁻² m).

The ceramic heater 100, having such a shape, was set in the vacuum chamber, and a silicon wafer for temperature evaluation, which was similar to that in Example 1, was placed in the ceramic heater 100. Further, the measurement of the gas leak amount and the evaluation of the temperature distribution of the silicon wafer were performed in procedures similar to the procedures in Example 1. In Example 12, the value r·Δ²/W·ln(W/Δ) was 3.5×10⁻⁹ (m²), and the gas leak amount was 50 sccm. The gas leak amount was 100 sccm or less, and the evaluation of the leak amount was determined to be satisfactory. In Example 12, the temperature difference ΔT was 1.0° C. The temperature difference ΔT was 2.0° C. or less, and the evaluation of the temperature distribution of the silicon wafer was determined to be satisfactory.

### Example 13

A ceramic heater 100 of Example 13 has a configuration similar to the configuration of the ceramic heater 100 of Example 1, except that the diameter 2r of each of the surrounding projected parts 157 was made to 20 mm (2.0×10⁻² m).

The ceramic heater 100, having such a shape, was set in the vacuum chamber, and a silicon wafer for temperature evaluation, which was similar to that in Example 1, was placed in the ceramic heater 100. Further, the measurement of the gas leak amount and the evaluation of the temperature distribution of the silicon wafer were performed in procedures similar to the procedures in Example 1. In Example 13, the value r·Δ²/W·ln(W/Δ) was 4.6×10⁻⁹ (m²), and the gas leak amount was 67 sccm. The gas leak amount was 100 sccm or less, and the evaluation of the leak amount was determined to be satisfactory. In Example 13, the temperature difference ΔT was 1.1° C. The temperature difference ΔT was 2.0° C. or less, and the evaluation of the temperature distribution of the silicon wafer was determined to be satisfactory.

### Comparative Example 1

A ceramic heater 100 of Comparative Example 1 was configured to have the height H1 of each of the surrounding projected parts, which was 150 μm and which was the same as the height H2 of each of the plurality of projected parts 156. In this case, the difference Δ between the height H2 and the height H1 was made to be of the same extent as the center line average roughness Ra (0.4 μm) in each of the top face 157a of the surrounding projected parts 157 and the top face 156a of the plurality of projected parts 156. In the comparative example 1, the ceramic heater 100 has a configuration similar to the configuration of the ceramic heater 100 of Example 1, except that the difference Δ between the height H2 and the height H1 was made to 0.4 μm (4.0×10⁻⁷ m).

The ceramic heater 100, having such a shape, was set in the vacuum chamber, and a silicon wafer for temperature evaluation, which was similar to that in Example 1, was placed in the ceramic heater 100. Further, the measurement of the gas leak amount and the evaluation of the temperature distribution of the silicon wafer were performed in procedures similar to the procedures in Example 1. In Comparative Example 1, the value r·Δ²/W·ln(W/Δ) was 6.3×10⁻¹² (m²), and the gas leak amount was 0 sccm. The gas leak amount was 100 sccm or less, and the evaluation of the leak amount was determined to be satisfactory. In Comparative Example 1, however, the temperature difference ΔT was 2.1° C. Since the temperature difference ΔT was 2.0° C. or more, and the evaluation of the temperature distribution of the silicon wafer was determined to be poor.

### Comparative Example 2

A ceramic heater 100 of Comparative Example 2 has a configuration similar to the configuration of the ceramic heater 100 of Example 1, except that the height H1 of each of the surrounding projected parts 157 was made to 100 μm and that the difference Δ between the height H2 and the height H1 was made to be 50 μm (5.0×10⁻⁵ m).

The ceramic heater 100, having such a shape, was set in the vacuum chamber, and a silicon wafer for temperature evaluation, which was similar to that in Example 1, was placed in the ceramic heater 100. Further, the measurement of the gas leak amount and the evaluation of the temperature distribution of the silicon wafer were performed in procedures similar to the procedures in Example 1. In Comparative Example 2, the value r·Δ²/W·ln(W/Δ) was 3.7×10⁻⁸ (m²), and the gas leak amount was 542 sccm. The gas leak amount exceeded 300 sccm, and the evaluation of the leak amount was determined to be poor. Note that in Comparative Example 2, the temperature difference ΔT was 1.8° C. The temperature difference ΔT was 2.0° C. or less, and the evaluation of the temperature distribution of the silicon wafer was determined to be satisfactory.

### Effect of Embodiment

In the embodiment and Examples 1 to 13, as described above, the ceramic heater 100 includes the disc-shaped ceramic base member 110 and the heater electrode 122 embedded in the ceramic base member 110. The plurality of projected parts 156 and the surrounding projected parts 157 are provided on the upper surface 111 of the ceramic base member 110. Each of the surrounding projected parts 157 is arranged in the periphery (surrounding) of one of the lift-pin holes 166, which are the through holes formed in the ceramic base member 110, so as to surround one of the lift-pin holes 166. In the case that the height (the length in the up-down direction 5) from the upper surface 111 of the ceramic base member 110 up to the top face 157a of each of the surrounding projected parts 157 is H1 (m), the height (the length in the up-down direction 5) from the upper surface 111 of the ceramic base member 110 up to the top surface 156a of each of the plurality of projected parts 156 is H2 (m), and the difference (H2−H1) between the height H2 (m) and the height H1 (m) is Δ (m), H1<H2 and 1×10⁻⁶ (m)≤Δ<50×10⁻⁶ (m) hold.

As in Examples 1 to 13, in a case where H1<H2 and 1×10⁻⁶ (m)≤Δ<50×10⁻⁶ (m) hold, it is possible to suppress the leak amount to be 300 sccm or less and to suppress the temperature difference ΔT to be 2.0° C. or less. This makes it possible to suppress the consumption amount of the gas in the case of attracting the wafer 10 by the vacuum suction and to suppress the generation of a heat spot at a part or location of the wafer 10 immediately above each of the surrounding projected parts 157.

Note that in Comparative Example 1, the height H1 of the surrounding projected parts 157 and the height H2 of the plurality of projected parts 156 were the same (H1=H2) and that the difference A between the height H2 and the height H1 was of a same extent as the center line average roughness Ra (0.4 μm) in each of the top face 157a of the surrounding projected parts 157 and the top face 156a of the plurality of projected parts 156. It was found that in a case where the difference Δ between the height H2 and the height H1 is smaller than 1 μm as described above, the temperature difference ΔT exceeded 2.0° C., and a heat spot was generated in the wafer 10, at a location immediately above each of the surrounding projected parts 157. Further, it was also found out, as in Comparative Example 2, that in a case where the difference A between the height H2 and the height H1 is 50 μm or more, it was not possible to suppress the leak amount to be 300 sccm or less, and that it was greatly difficult to attract the wafer 10 by the vacuum suction.

As in Examples 1 to 13 as described above, in a case where 3×10⁻⁶ (m)≤Δ≤30×10⁻⁶ (m) holds, it is possible to suppress the leak amount to be less than 230 sccm and to suppress the temperature difference ΔT to be less than 1.8° C. This makes it possible to suppress the consumption amount of the gas in the case of attracting the wafer 10 by the vacuum suction and to suppress the generation of a heat spot at a part or location of the wafer 10 immediately above each of the surrounding projected parts 157.

As in Examples 1, 3, 4, 7, and 8 to 13 as described above, in a case where 5×10⁻⁶ (m)≤Δ≤15×10⁻⁶ (m) holds, it is possible to suppress the leak amount to be 70 sccm or less and to suppress the temperature difference ΔT to be 1.2° C. or less. This makes it possible to further suppress the consumption amount of the gas in the case of attracting the wafer 10 by the vacuum suction and to further suppress the generation of a heat spot at a part or location of the wafer 10 immediately above each of the surrounding projected parts 157.

As in Examples 1 to 5 and 7 to 13 as described above, in a case where the value r·Δ²/W·ln(W/Δ) is 1.0×10⁻⁸ (m²) or less, it is possible to suppress the leak amount to be 120 sccm or less and to suppress the temperature difference ΔT to be 1.4° C. or less. This makes it possible to suppress the consumption amount of the gas in the case of attracting the wafer 10 by the vacuum suction and to suppress the generation of a heat spot at a part or location of the wafer 10 immediately above each of the surrounding projected parts 157.

### Modification

The embodiment, as described above, is merely an example and may be changed as appropriate. For example, the shape and the size of the ceramic base member 110 are not limited to or restricted by those of the above-described embodiment and may be changed as appropriate. Further, the size, such as the height, the width, etc., of the annular projected part 152, the shape of the top face 152a of the annular projected part 152, the magnitude of the center line average roughness Ra in the top face 152a of the annular projected part 152 may be changed as appropriate. The height of each of the plurality of projected parts 156, the shape of the top face 156a, and the magnitude of the center line average roughness Ra in the top face 156a of the plurality of projected parts 156 may be changed as appropriate. For example, it is not necessarily indispensable that the shape of the top face 156a of each of the plurality of projected parts 156 is circular, and the shape of the top face 156a of each of the plurality of projected parts 156 may be, for example, an appropriate shape such as a square, etc.

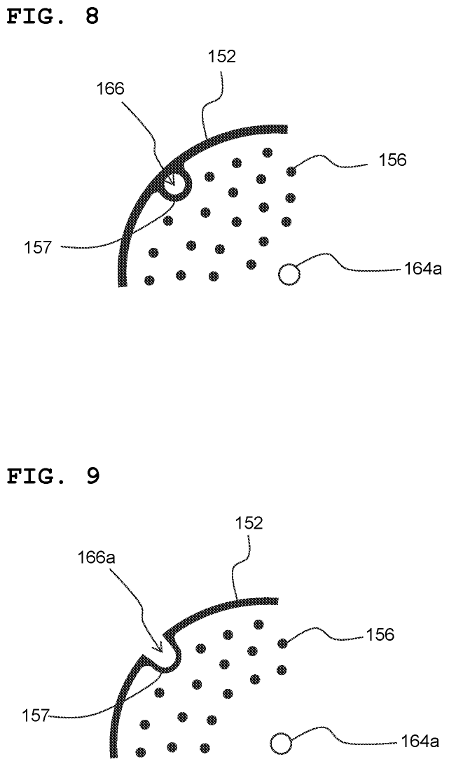

Further, it is not necessarily indispensable that the shape of the top face 157a of each of the surrounding projected parts 157 is annular (ring-shaped). For example, in a case where a lift-pin hole 166 is located in the vicinity of the annular projected part 152, it is allowable, as depicted in FIG. 8, that the annular projected part 152 and a surrounding projected part 157 are arranged to be continuous to each other, and that the annular projected part 152 and the surrounding projected part 157 cooperate to surround the periphery of the lift-pin hole 166. Also, in this case, it is possible to suppress the consumption amount of the gas in the case of attracting the wafer 10 by the vacuum suction and to suppress the generation of a heat spot at a part or location of the wafer 10 immediately above each of the surrounding projected parts 157, in a similar manner as in the embodiment and Examples 1 to 13 as described above.

In the embodiment and Examples 1 to 13 as described above, although the surrounding projected parts 157 are provided, respectively, on the peripheries of all the lift-pin holes 166, the present disclosure is not limited to such an aspect. It is also allowable to provide a surrounding projected part 157 on the periphery of any one of the plurality of lift-pin holes 166. Further, although the lift-pin hole 166 is the through hole, the present disclosure is not limited to such an aspect. For example, as depicted in FIG. 9, it is allowable that a cutout part 166a is provided on an outer circumferential part of the ceramic base member 110 instead of providing the lift-pin hole 166 and that a surrounding projected part 157 is provided so as to surround the cutout part 166a. In this case, the radius of the inner diameter of the cutout part is “r”, and the width of the inner diameter is “W”. Also, in this case, it is possible to suppress the consumption amount of the gas in the case of attracting the wafer 10 by the vacuum suction and to suppress the generation of a heat spot at a part or location of the wafer 10 immediately above each of the surrounding projected parts 157, in a similar manner as in the embodiment and Examples 1 to 13 as described above.

In the above-described embodiment, the molybdenum, the tungsten, or an alloy including the molybdenum and/or the tungsten is used as the material forming the heater electrode 122. The present disclosure, however, is not limited to such an aspect. For example, it is allowable to use a metal or an alloy different from the molybdenum and the tungsten. Further, the electrode 120 includes the heater electrode 122 as the heating element. It is not necessarily indispensable, however, that the electrode 120 includes the heater electrode 122 as the heating element; it is allowable, for example, the electrode 120 includes a high frequency electrode.

In the above-described embodiment, although the ceramic heater 100 includes the heater electrode 120 embedded in the ceramic base member 110, the present disclosure is not limited to such an aspect; it is allowable that the heater electrode 120 is not embedded in the ceramic base member 110. For example, it is also allowable that the heater electrode or a high-frequency electrode as the heating element is adhered to a rear surface 113 (see FIG. 2) of the ceramic base member 110.

In the foregoing, although the explanation has been given by using the embodiment and the modifications thereof of the present disclosure, the technical scope of the present disclosure is not limited to the scope or range of the above-described description. It is apparent to a person skilled in the art that various changes or improvements can be made to the above-described embodiment. It is also apparent from the description of the claims to the person skilled in the art that an aspect obtained by adding such a change or improvement is also included in the technical scope of the present disclosure.

The order of execution of the respective processes in the production method indicated in the specification and in the drawings can be executed in an arbitrary order unless the order is clearly described and/or unless the output of a preceding process is used in a succeeding process. Even in a case where the explanation is given by using, for the sake of convenience, the terms such as “at first”. “first”. “next”. “then”, etc., it is not meant that it is necessarily indispensable that the respective processes are executed in this order.

What is claimed is:

1. A ceramic heater comprising:
a ceramic base member having a disc-shape and including an upper surface, a lower surface facing the upper surface in an up-down direction and a through hole or a cutout part penetrating the ceramic base member from the upper surface to the lower surface; and
a heating element which is embedded in the ceramic base member or arranged on the lower surface of the ceramic base member,
wherein the ceramic base member includes:
a plurality of projected parts configured to project upward to be higher than the upper surface of the ceramic base member; and
a surrounding projected part arranged in a periphery of the through hole or the cutout part in the upper surface of the ceramic base member and configured to project upward to be higher than the upper surface of the ceramic base member, and
H1<H2, and
$$1 \times 1 {0}^{- 6} ( m ) \leq Δ < 50 \times 1 {0}^{- 6} ( m )$$
are satisfied, wherein a length in the up-down direction from the upper surface of the ceramic base member to a top face of the surrounding projected part is H1 (m), a length in the up-down direction from the upper surface of the ceramic base member to a top surface of each of the plurality of projected parts is H2 (m), and a difference (H2−H1) between the length H2 (m) and the length H1 (m) is Δ (m).

2. The ceramic heater according to claim 1, wherein the difference Δ (m) between the length H2 (m) and the length H1 (m) satisfies 3×10⁻⁶ (m)≤Δ≤30×10⁻⁶ (m).

3. The ceramic heater according to claim 2, wherein the difference Δ (m) between the length H2 (m) and the length H1 (m) satisfies 5×10⁻⁶ (m)≤Δ≤15×10⁻⁶ (m).

4. The ceramic heater according to claim 1, r·Δ²/W·ln(W/Δ)≤1.0×10⁻⁸ (m) is satisfied, wherein a width in a radial direction of the surrounding projected part is W (m) and an inner diameter of the surrounding projected part is r (m).
